(19) United States
(12) Patent Application Publication
(10) Pub. No.: US 2009/0246371 A1
(43) Pub. Date: Oct. 1, 2009

(54) METHOD OF FORMING THIN LAYERS BY A THERMALLY ACTIVATED PROCESS USING A TEMPERATURE GRADIENT ACROSS THE SUBSTRATE

(76) Inventors: Fabian Koehler, Dresden (DE); Falk Graetsch, Dresden (DE)

Correspondence Address: WILLIAMS, MORGAN & AMERSON, 10333 RICHMOND, SUITE 1100, HOUSTON, TX, 77042, US

(21) Appl. No.: 12/275,304

(22) Filed: Nov. 21, 2008

(30) Foreign Application Priority Data
Mar. 31, 2008 (DE) 10 2008 016 429.1

(51) Int. Cl. C23C 16/00

(52) U.S. Cl. 427/248.1

(57) ABSTRACT

A thermally activated batch process is disclosed for forming thin material layers in semiconductor devices including the establishment of an overheating temperature profile prior to actually forming a material layer, for instance, by deposition, so that a gas depletion at the centre of the substrate during the deposition process be compensated for. Thus, enhanced thickness uniformity for thin material layers in the range of 1 to 50 nanometers may be obtained without additional process time or even at a reduced process time.

### BACKGROUND OF THE INVENTION

1. Field of the Invention

Generally, the present disclosure relates to chemical vapor deposition (CVD) techniques used for forming thin material layers above a substrate during the fabrication of microstructure devices, such as integrated circuits and the like.

2. Description of the Related Art

The dimensions of modem microstructure devices are steadily shrinking to provide both improved device performance and packing density. For instance, for complex integrated circuits, both advantages are mainly obtained by steadily shrinking the feature sizes of the individual circuit elements, such as field effect transistors, whereby critical dimensions, i.e., minimum feature sizes that can be reproducibly printed onto the substrate, are currently approaching 0.05 μm and less, with the prospect of further scaling of dimensions in future device generations. The fabrication of modem microstructure devices, such as integrated circuits having an ultra high packing density, requires a large number of individual process steps, including processes such as lithography, deposition, etching, annealing, implantation, planarization processes and the like. Many of these individual process steps may represent critical processes in the sense that even relatively small deviations from a specified process window may result in a significant change of the overall characteristics of the microstructure devices, such as the electrical performance, when sophisticated integrated circuits are considered.

For example, highly complex integrated circuits may typically be formed on the basis of CMOS technology, in which field effect transistors represent the most important circuit elements that substantially determine the overall performance of the entire device. During the fabrication of complex integrated circuits using CMOS technology, millions of complementary transistors, i.e., N-channel transistors and P-channel transistors, are formed on a substrate including a crystalline semiconductor layer. A field effect transistor, irrespective of whether an N-channel transistor or a P-channel transistor is considered, comprises so-called PN junctions that are formed by an interface of highly doped drain and source regions with an inversely or weakly doped channel region disposed between the drain region and the source region. The conductivity of the channel region, i.e., the drive current capability of the conductive channel, is controlled by a gate electrode formed near the channel region and separated therefrom by a thin insulating layer. The conductivity of the channel region, upon formation of a conductive channel due to the application of an appropriate control voltage to the gate electrode, depends on the dopant concentration, the mobility of the charge carriers, the distance between the source and drain regions, which is also referred to as channel length, and the channel width. Thus, the reduction of the channel length may be a dominant design criterion for accomplishing an increased operating speed of individual transistors and also for enhancing the overall packing density of the integrated circuit.

The shrinkage of the transistor dimensions, however, involves a plurality of issues associated therewith which have to be addressed so as to not unduly offset the advantages obtained by steadily decreasing the channel length of MOS transistors. One issue associated with reduced gate lengths is the occurrence of so-called short channel effects, which may result in a reduced controllability of the channel conductivity. Short channel effects may be countered by certain design techniques, which may involve an appropriate adaptation of the thickness of the gate insulation layer for a given material composition thereof, and an appropriate vertical and lateral profile of the drain and source regions so as to establish the desired dopant gradient at the PN junctions, which finally determine the effective channel length of the field effect transistor and the like. Respective dopant profiles may typically be formed on the basis of an ion bombardment, wherein the vertical profile, i.e., the penetration depth and the distribution of the dopant species in the depth direction, may be controlled on the basis of parameters, such as implantation energy and dose, if an ion implantation process is considered. On the other hand, the lateral profile may be controlled by providing appropriately designed implantation masks to appropriately shield the incoming ions from being incorporated into undesired device regions. Thereafter, the dopant profile obtained by the ion bombardment may be further modified by performing respective anneal processes to activate the incorporated dopant species and also to re-crystallize implantation-induced lattice damage. Thus, the effective gate length and, hence, the resulting performance of field effect transistors may be substantially determined by the overall dopant profile, which is typically established on the basis of appropriately designed implantation masks, which in turn are formed by depositing appropriate material layers and etching the same on the basis of appropriately designed etch techniques. For example, during a typical process for forming field effect transistors, the gate electrode or a respective placeholder structure may be formed prior to actually defining the drain and source regions by ion implantation so as to obtain a self-aligned process step, wherein the gate electrode may act as an implantation mask. In order to obtain the desired lateral profiling, the effective lateral dimensions of the gate electrode structure may have to be appropriately adjusted to a respective implantation process in order to obtain the desired shielding effect. For this purpose, self-aligned sidewall spacer techniques have been established, in which an appropriate material layer may be deposited and may be subsequently etched to form respective sidewall spacer elements, which may then define the point of entry of a respective dopant species during an ion implantation process. Consequently, the initial layer thickness formed above the patterned surface of the device may have a significant influence on the finally obtained lateral dimension of the implantation mask and, hence, on the electrical performance of the field effect transistor, since even relatively small non-uniformities in the dopant profile may result in a significant change of the transistor characteristics.

Also, in many other cases, the deposition of moderately thin material layers may have a significant influence on the overall device performance, wherein a precise control of the layer thickness may even gain in importance as critical feature sizes are continuously being reduced in size. One well-established process technique for forming thin material layers such as silicon nitride, silicon dioxide, polysilicon and the like is chemical vapor deposition (CVD) performed at moderately low pressure ranges, referred to as low pressure chemical vapor deposition (LPCVD), which represents a thermally activated deposition process. In a CVD process, a gaseous ambient is established near a deposition surface and respective precursor components undergo a chemical reaction in the vicinity of the deposition surface, the product of which may then be deposited, thereby increasingly building up a layer of the desired material composition. During the deposition process, the deposition rate significantly depends on the temperature at or in the vicinity of deposition surface and the concentration of the respective gas components. Thus, CVD reactors for thermally activated processes have been developed, in which a plurality of substrates are typically processed by establishing an appropriate deposition ambient to controllably deposit the material under consideration. For highly sophisticated deposition recipes, however, it has been observed that a certain degree of thickness non-uniformity may occur, which significantly affects the performance of semiconductor devices, in particular, if a target layer thickness in the range of 1-50 nm is to be obtained by the deposition techniques. As previously indicated, the deposition of a gate insulation layer, the deposition of a spacer layer and the like may represent highly critical process steps in sophisticated integrated circuits, as will be described in more detail with reference to FIGS. 1a-1c.

FIG. 1a schematically illustrates a cross-sectional view of a semiconductor device 100 at a manufacturing stage in which one or more material layers of well-defined thickness have to be formed above a semiconductor layer 102 which, in turn, is provided above a substrate 101. For convenience, it may be assumed that the substrate 101 and the semiconductor layer 102 are provided as a silicon material, wherein it should be appreciated that any other appropriate materials may be used. Moreover, in the manufacturing stage shown, a plurality of gate electrode structures 103 may be provided, for instance, in the form of polysilicon lines, having a gate length, i.e., in FIG. 1a, the horizontal dimension of the gate electrode structures 103, of, for instance, 50 nm and less. Furthermore, the gate electrode structures 103 may be formed on respective gate insulation layers 104 having a thickness of one to several nm in sophisticated applications. The gate insulation layers 104 may be formed of any appropriate material, such as silicon dioxide, silicon oxynitride and the like. Furthermore, a spacer layer 105 may be formed on the semiconductor layer 102 and the gate electrode structures 103 in a highly conformal manner, i.e., the thickness of the spacer layer 105 should be very similar at any device region, irrespective of the topography of the under-lying surface.

Typically, the semiconductor device 100 may be formed on the basis of the following processes. After forming appropriate isolation structures (not shown) for defining active regions in the semiconductor layer 102, which may be established by well-established process techniques, which may also involve the deposition of thin material layers, the gate insulation layer 104 may be formed, for instance, by oxidation and/or deposition, wherein, also in this case, a high degree of process uniformity may be required to obtain substantially uniform transistor characteristics. Thereafter, the gate electrode material may be deposited, for instance, by LPCVD, as previously explained, with a required thickness according to the overall process and device requirements. That is, the thickness of the gate electrode material may typically be selected such that a desired degree of ion block effect may be accomplished during a subsequent process sequence for forming drain and source regions on the basis of an ion implantation process, while, on the other hand, the thickness may have to be kept below a specified level to avoid a pronounced surface topography, i.e., respective aspect ratio of the gate electrode structures 103 may result in complex process conditions during the subsequent process steps, for instance, for the deposition of further materials, such as the layer 105 and the like. Thus, also in this case, a precisely controlled thickness of the gate electrode material may be required. Thereafter, the gate electrode material and the gate dielectric material may be patterned on the basis of highly advanced lithography and etch techniques to obtain the gate electrode structures 103 and the gate insulation layers 104.

Next, a spacer may be formed on sidewalls of the gate electrode structures 103 by depositing an appropriate material, such as silicon dioxide and the like, and anisotropically etching the same. Thereafter, an ion implantation process may be performed to generate a shallow portion of drain and source regions on the basis of specifically selected implantation parameters. Also, in this case, sophisticated CVD deposition recipes may be used. As an example for performing a critical LPCVD process, it may be referred to as deposition process 106 for forming the spacer layer 105, wherein it should be appreciated that similar criteria may also apply to any of the previously deposited layers, such as the gate insulation layer 104, the gate electrode material for forming the structures 103, any offset spacers and the like. During the deposition process 106, an appropriate gaseous ambient may be established in combination with a required process temperature. For example, the spacer layer 105 may be comprised of silicon nitride in combination with a thin etch stop layer (not shown) of silicon dioxide, which may also deposited by LPCVD. The gaseous ambient of the process 106 may be established on the basis of ammonia and a silane derivative or similar gas components at temperatures of approximately 750-850° C. at a pressure of approximately 200-300 mTorr in a furnace. It turns out, however, that the thickness 105T may vary along the diameter of the substrate 101, wherein usually an increased thickness may be observed at the edge 101G of the substrate 101, while a reduced thickness may be obtained at the center 101C of the substrate 101. It should be appreciated that the dimensions as illustrated in FIG. 1a are not to scale, in particular, the lateral dimension of the substrate 101 is shown to be extremely reduced compared to the lateral dimensions of the gate electrode structures 103.

FIG. 1b schematically illustrates a typical deposition reactor 150 that may be used for forming a thin material layer, such as the layer 105. For example, during the process 106, a plurality of substrates 101 may be positioned in the reactor 150, which may comprise a plurality of temperature zones 151A, 151B, 151C, depending on the overall configuration of the reactor 150. Furthermore, the reactor 150 may comprise appropriate means for heating the interior of the reactor 150 and for establishing the desired gaseous ambient by establishing a respective gas flow. For convenience, any such well-established components are commonly referred to as reactor components 152 that include any appropriate heating elements and gas flow components as required for establishing the ambient 106 at a specified process temperature.

FIG. 1C schematically illustrates a graph illustrating the temperature conditions in the reactor 150 or at least in one of the temperature zones 151A, 151B, 151C during the deposition process 106 according to well-established process techniques. After positioning the substrates 101 in the reactor 150, a respective gas ambient may be established, which may comprise an inert species, such as nitrogen and the like. Thereafter, during a first phase, the temperature in the reactor 150 may be increased at a specific rate to finally reach a desired process temperature. In this context, the process temperature is to be understood as the temperature of the interior of the reactor 150, i.e., of respective heating elements, the gases in contact with the heating element and the like. It should be appreciated that this temperature may not necessarily represent the actual temperature at the surface of substrates 101, since, during the ramp-up phase, a thermal equilibrium may not be fully established across the substrates 101. After reaching the process temperature, therefore, a temperature stabilization phase typically follows, in which substantially a thermal equilibrium may be accomplished in the substrates 101 so that a surface temperature thereof may substantially correspond to the desired process temperature. After the temperature stabilization period, the actual deposition phase may be initiated by introducing the reactive gas components as, for instance, specified above, thereby obtaining a specific deposition rate which may substantially depend on the temperature at or in the vicinity of the surface of the substrates 101, which, according to the previous temperature stabilization phase, substantially corresponds to the process temperature, and the concentration of the gaseous components, which is determined by the overall configuration of the reactor 150 and the respective gas flow established therein.

After the deposition phase, the reactor 150 may be purged on the basis of a substantially inert gas component, thereby also stopping actual deposition process and, finally, the reactor 150 may be cooled down. As explained above, after the deposition process 106, a significant variation in layer thickness may be observed between the substrate edge 101G and the substrate center 101C, which is believed to be caused by a non-uniform gas concentration across the substrate 101, since typically the gas flow may vary from the substrate edge 101G to the center 101C of the substrate, thereby resulting in a depletion of the reactive gas components at the center 101C, which may thus reduce the overall deposition rate.

For this reason, it has been proposed to compensate for the effect of gas depletion at the center 101C of the substrates by reducing the process temperature of the reactor 150 during the deposition phase, as indicated by curve A, in order to establish a reduced temperature at the substrate edge 101G compared to the center 101C during the deposition, as typically the edge 101G may cool down faster than the center 101C of the substrates 101, thereby establishing a reduced deposition rate at the center of the substrates 101. In this case, a varying process temperature may be established and thus a certain temperature range Tp may have to be used, which may also include non-ideal temperatures for the deposition process under consideration. Thus, the global deposition rate may also vary due to the varying process temperature and may result in longer overall process times. Furthermore, in some cases, a minimum critical temperature for the deposition process under consideration may fall short, and, therefore, to obtain the desired layer thickness, the deposition may have to be interrupted to re-establish a valid process temperature, before performing another deposition cycle, which may further contribute to increased process times.

The present disclosure is directed to various methods that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure relates to process techniques for forming material layers for microstructure devices, such as semiconductor devices, on the basis of a thermally activated process, such as a CVD deposition process, an oxidation process and the like, in which a local variation of the concentration of reactive gas components may be compensated for by an appropriately designed temperature gradient, which may be established prior to the actual phase for forming the material layer under consideration, which may thus enable, in some illustrative embodiments, performing the actual process of forming the material layer under substantially constant process temperature conditions. The temperature gradient may be established prior to the actual phase for forming the material layer under consideration, for instance, the deposition phase, by overheating the substrate prior to initiating the formation of the material layer by introducing the reactive gas component. Consequently, the global process temperature during the actual phase for forming the material may be selected within a specified range or may be held substantially constant in order to provide a desired high global deposition rate, while the previously established temperature gradient provides the desired low difference in deposition rate between substrate edge and the substrate center. In this manner, a uniform layer thickness may be achieved across the substrate, thereby enabling the formation of thin material layers, for instance, in the range of approximately 1-40 nm, which may directly translate into enhanced device characteristics for sophisticated semiconductor devices.

One illustrative method disclosed herein relates to forming a material layer of a microstructure device. The method comprises generating a temperature profile in a process reactor comprising a plurality of substrates, wherein the temperature profile includes a temperature above a predetermined process temperature range. The method further comprises establishing a process temperature within the predetermined process temperature range in the process reactor after generating the temperature profile. Additionally, the method comprises introducing a precursor gas component to initiate the formation of the material layer above the plurality of substrates at the process temperature maintained within the predetermined process temperature range.

Another illustrative method disclosed herein comprises determining a target temperature gradient across a specified type of surface for reducing a non-uniformity during a thermally activated process for forming a material layer above the specified type of surface. The method further comprises generating a temperature profile in a reactor comprising one or more substrates on the basis of the target temperature gradient, wherein each of the one or more substrates comprises a surface of the specified type. Additionally, the method comprises introducing a reactive gas component into the reactor at a substantially constant process temperature to initiate the formation of the material layer.

A still further illustrative method disclosed herein comprises creating a temperature gradient across a surface of each of a plurality of substrates, wherein the temperature gradient includes at least one surface temperature that is above a predefined process temperature, and wherein the surface comprises a device feature. The method further comprises forming a material layer above the surface and the device feature substantially at the process temperature and removing a portion of the material layer to form a sidewall spacer at sidewalls of the device feature.

### BRIEF DESCRIPTION OF THE DRAWINGS

The disclosure may be understood by reference to the following description taken in conjunction with the accompanying drawings, in which like reference numerals identify like elements, and in which:

FIG. 1a schematically illustrates a cross-sectional view of a semiconductor device during a manufacturing phase for forming a thin material layer on the basis of conventional process techniques;

FIG. 1b schematically illustrates a cross-sectional view of a CVD reactor;

FIG. 1c schematically illustrates a graph illustrating a typical temperature progression during various phases of the LPCVD deposition process, according to conventional strategies;

FIG. 2a schematically illustrates a graph illustrating the temperature profiles during a thermally activated process for forming a thin material layer including an overheating phase prior to the actual phase of forming the material, according to illustrative embodiments;

FIG. 2b schematically illustrates the temperature distribution across a substrate obtained prior to the actual phase for forming the material layer, according to illustrative embodiments; and

FIGS. 2c-2d schematically illustrate cross-sectional views of a semiconductor device during various manufacturing phases in depositing and patterning a thin material layer so as to adjust critical device characteristics, according to illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

Generally, the present disclosure relates to techniques for forming material layers with improved thickness uniformity across the substrate by appropriately adapting a temperature gradient prior to actually forming the material layer, i.e., depositing the layer, performing a surface treatment, such as an oxidation, and the like. In some illustrative embodiments, the techniques may be applied to thermally activated CVD deposition processes performed at low pressure conditions, which may be performed in reactors including a plurality of substrates. For instance, material layers, such as silicon nitride, polysilicon, silicon dioxide and the like, may be formed by low pressure chemical vapor deposition (LPCVD) techniques with enhanced across-substrate uniformity on the basis of the techniques described herein. Furthermore, the principles disclosed herein may also be applied to other processes for forming material layers on the basis of a reactive gas component, wherein the reaction rate may depend on the local gas concentration and the local temperature, as may be the case in high temperature oxidation processes and the like. The temperature gradient may be established by heating the reactor up to an “excess” process temperature, thereby “overheating” the substrate. Thereafter, the process temperature may be reduced to the required process temperature range and may be maintained within this range, for instance, in some illustrative embodiments, a substantially constant process temperature may be established during the actual phase for forming the material layer, wherein the previous “overheating” of the substrates may result in a temperature gradient, which may therefore compensate for or at least reduce the non-uniformity of the deposition rate, which may otherwise be induced by a locally varying concentration of the reactive gas components.

In some illustrative aspects disclosed herein, the overheating temperature profile prior to the actual deposition or surface treatment phase may be established on the basis of a target temperature gradient that may be determined so as to obtain a substantially uniform deposition rate across the substrate. In other illustrative embodiments, an intentionally introduced degree of thickness non-uniformity may be created, if deemed appropriate for compensating for non-uniformities of preceding or subsequent processes. For example, when depositing a spacer layer for defining an effective gate length of transistor devices, a systematic variation of transistor characteristics may be compensated for or reduced by adapting the local spacer width on the basis of a respectively varying layer thickness. Furthermore, since a desired process temperature range may be maintained during the actual phase for depositing or otherwise forming the material layer under consideration, process cycle times may be maintained at substantially the same value or may even be reduced compared to conventional strategies, in which a significantly varying process temperature may be used during the actual deposition phase.

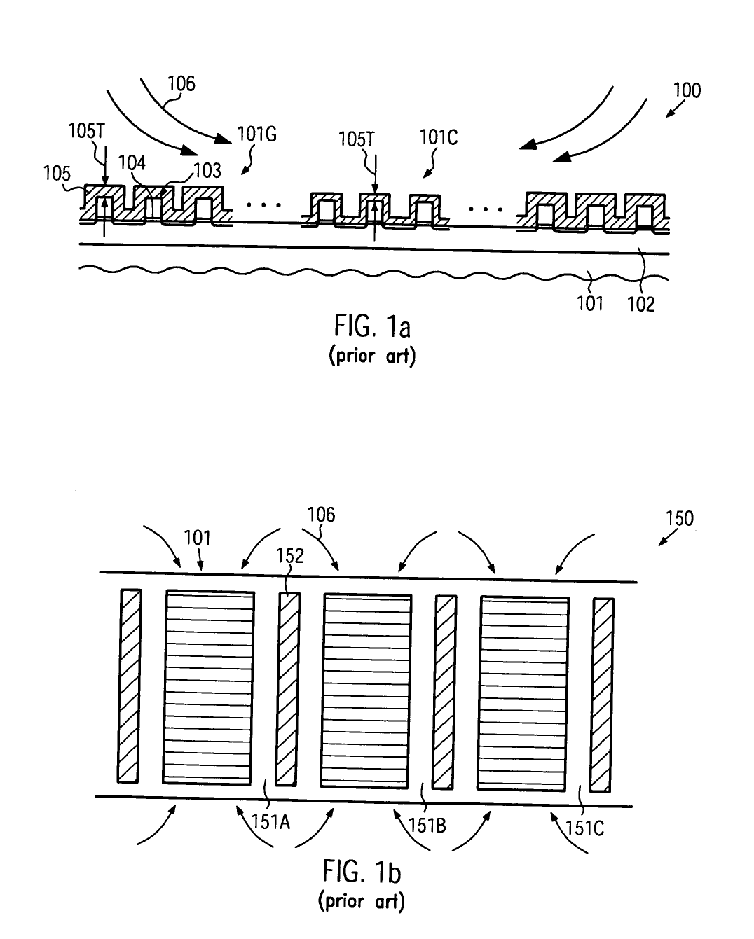

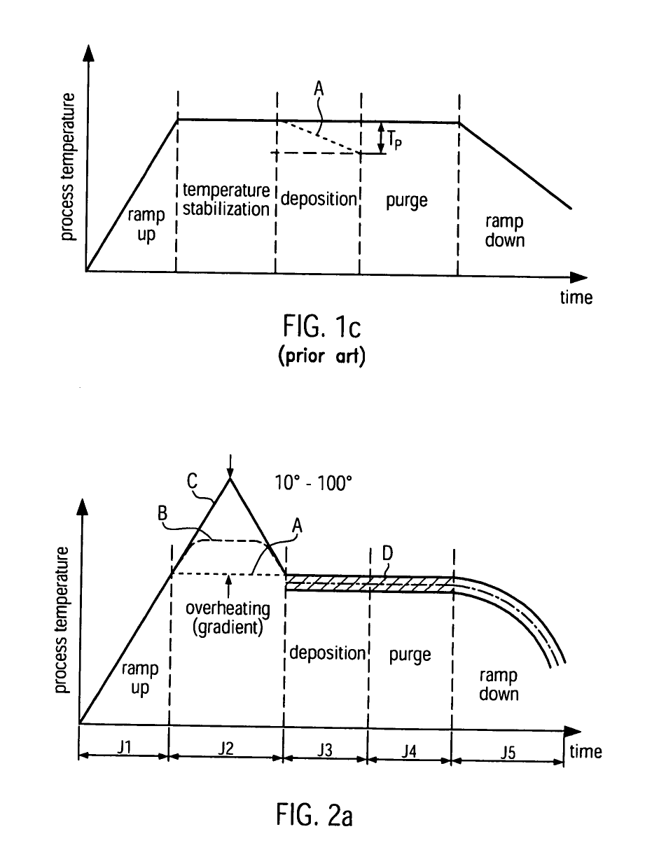

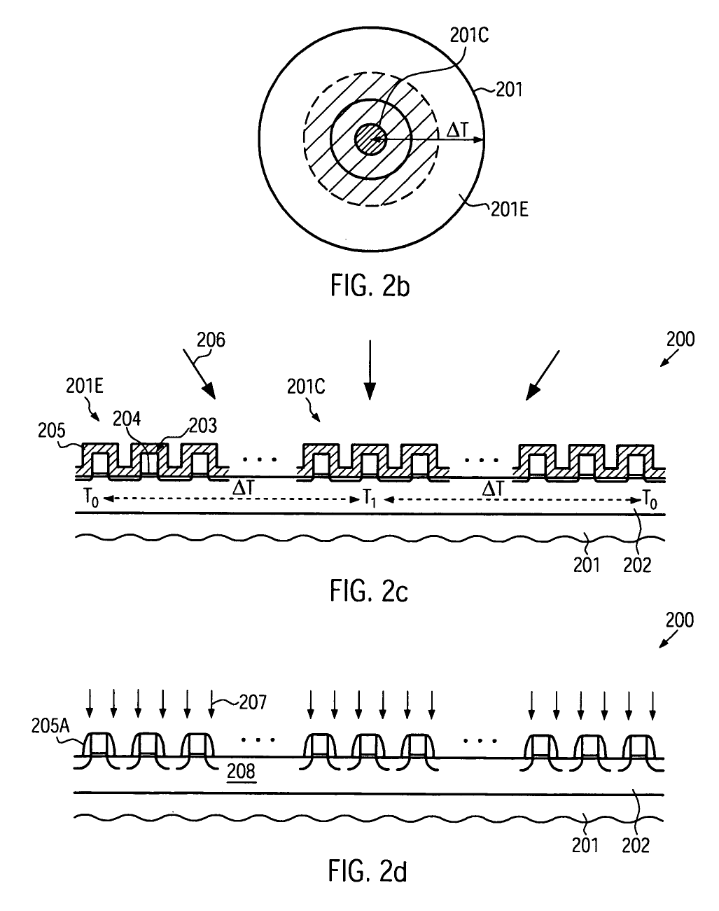

FIG. 2a schematically illustrates the progression of the process temperature during a process for forming a thin material layer over time according to the principles disclosed herein. For a respective thermally activated process for forming a material layer, for instance, in the form of materials as specified above, with a thickness of approximately of 50 nm and less, for instance, in the range of approximately 1-40 nm, the respective process ambient may typically be established with a process reactor, such as the reactor 150 as previously described with reference to FIG. 1b, in which a plurality of substrates may be concurrently processed. Due to the respective moderately low process pressure, for instance, in the range of several mTorr to several hundred mTorr, which may be required for a plurality of process recipes, including LPCVD recipes, high temperature oxidation processes and the like, the reaction rate and thus the rate at which material of the material layer may form, may significantly depend on the local temperature at or in close proximity to the substrate surface and the concentration of the reactive gas components. Typically, the mechanisms for distributing the reactive gas components within the reactor and the mechanism for establishing the temperature of the substrates may be similar in the sense that the edge regions of the substrate may interact more intensively with the reactor ambient compared to the substrate center. However, contrary to the concentration variation across the substrate which may be caused by the gas flow dynamics in the reactor, the temperature profile across the substrate may be controlled by appropriately adapting the process temperature profile, i.e., the profile of the temperature of the reactor ambient, by taking advantage of the fact that the edge regions of the substrate may respond faster to a change of the thermal conditions in the reactor ambient. That is, by establishing a temperature profile prior to the actual reactive phase such that, globally, the desired process temperature range is exceeded, the average temperature of the substrate may be raised above the process temperature. During this over-heating phase, the temperature at the substrate center may be raised above the desired process temperature, even if the substrate edge responds faster to the applied process temperature, and subsequently the process temperature may be adjusted to the desired value or value range, wherein the faster responding substrate edge may also adapt the process temperature, while the center is still on a higher temperature level. Thus, the process temperature established in the reactor may result in a positive temperature gradient from the center to the edge. Although this temperature gradient may decrease during the actual reactive process for forming the desired material layer, generally, a specified average temperature gradient may prevail during the deposition or surface treatment phase, which may thus appropriately compensate for the reduced concentration at the substrate center. Hence, the average temperature gradient may be substantially determined by the temperature at the substrate center and the substrate edge at the point in time of initiating the actual deposition or surface treatment process, the desired process temperature of this phase, the thermal characteristics of the substrate and the duration of the reactive phase. For otherwise constant conditions, the average temperature gradient may be controlled by the “initial” temperature gradient, which may be referred to simply as (positive) temperature gradient, although the value of this temperature gradient may be varying during the deposition or surface treatment phase.

An appropriate temperature gradient may be established by defining a process temperature profile, as is, for instance, shown in FIG. 2a. In this case, a ramp-up phase may be used, which may be considered as a phase in which a process temperature is raised up to a level that substantially corresponds to a desired process temperature range. Since, according to the principles disclosed herein, however, increased temperature values may be used prior to the actual deposition or treatment phase, the distinction between a ramp-up phase and an overheating phase, as indicated by the time intervals in J1 and J2 in FIG. 2a, may be arbitrary to a certain degree. In any case, a process temperature above the desired process temperature range, indicated as the hatched area D, for the deposition phase or treatment phase J3 may be applied to obtain the desired overheating effect. For instance, the curves B and C illustrate exemplary temperature profiles that may be appropriate for “over-heating” a substrate, thereby creating a temperature at the center of the substrate that is above the process temperature range, as previously explained. Furthermore, curve A represents an example of a conventional strategy, as previously explained with reference to FIG. 1c, in which a temperature stabilization step is used. Thus, in the strategy corresponding to the conventional profile according to curve A, it is attempted to reach a thermal equilibrium state between the substrate edge and the substrate center so as to obtain a substantially uniform temperature distribution. Contrary to this approach, the overheating, as represented by curves C and B, results in an increased temperature at the center at the beginning of the interval J3 due to the fast responding edge. Thus, during the overheating interval J2, depending on the overall shape of the respective profiles, the substrate edge may heat up faster than at the center, thereby establishing (negative) temperature gradient, which will also result in a temperature raise at the center, however less pronounced compared to the edge. After reducing the process temperature so as to reach the desired process temperature at the beginning of the interval J3, the edge will again follow the process temperature more quickly while the center may have an increased temperature. Thus, upon reaching the required process temperature at J3, which, in some illustrative embodiments, may represent a substantially constant temperature, as indicated by curve D, the global conditions for a chemical reaction may be maintained at a desired level, while, nevertheless, a locally increased temperature at the substrate center may provide appropriate compensation or even overcompensation, depending on the desired process output.

After a respective process time selected to obtain the desired layer thickness, the introduction of the reactive gas components may be discontinued and the reactor 150 may be purged, as indicated by interval J4, similarly as in conventional approaches. Thereafter, the process temperature may be ramped down during the interval J5 with a desired rate according to well-established recipes. It should be appreciated that the overheating phase J2 may be comparable in duration with the conventional temperature stabilization period, as shown in FIG. 1c, thereby obtaining comparable process times at enhanced thickness uniformity or obtaining a desired intentionally modified thickness profile. In other cases, the overheating phase J2 may be shorter compared to the conventional temperature stabilization step, thereby even reducing the overall cycle time. For example, during the generation of the profiles in the overheating period J2, such as the curves B and C, ramp-up and/or ramp-down rates of approximately 3-10° C. per minute may be used. Furthermore, a maximum temperature in the overheating phase J2 may be approximately 10-100° C. above the desired process temperature range or the substantially constant process temperature represented by curve D.

FIG. 2b schematically illustrates a temperature distribution of a substrate 201. As illustrated, the temperature at the center 201C may be higher compared to the temperature at the edge 201E, at least at the final phase of the overheating period J2 and at the beginning and during the phase J3. That is, at least at the beginning of the phase J3, the temperature at the center 201C may be higher compared to the edge in the period J3, wherein both temperatures may be “near” the desired process temperature, thereby providing the possibility of locally compensating for or overcompensating for a gas depletion at the center 201C as may typically occur during the deposition or treatment phase J3 in a reactor having a configuration as shown in FIG. 1b. For example, the deposition rate R may be evaluated as a function of the locally prevailing temperature T and the reactive gas concentration C at an established working point—characterized by T₀, C₀—by the following equation.:

R(T, C)=R(T₀, C₀)+A ΔT+B ΔC,

wherein A, B represent constants determined by reactor-specific and recipe-specific characteristics. In good approximation, the concentration may be written as:

C=C₀+ΔC and

the temperature may be approximated by:

T=T₀+ΔT

If, for instance, a substantially uniform deposition rate is to be achieved, i.e.:

R(T,C)=R(T₀,C₀)

which also means that substantially the same deposition rate may be achieved at the center and the edge of the substrate, since these areas are defined by different temperature and concentration values, the following condition has to be fulfilled:

A ΔT+B ΔC=0, or

ΔT=−B/A ΔC

In this equation, the temperature gradient ΔT represents the value required for obtaining a substantially constant deposition rate at the edge and the center of the substrate, thereby compensating for a difference in the local gas concentration. It should be appreciated, however, that other conditions may be established, for instance, an overcompensation may be achieved by appropriately determining a respective temperature gradient ΔT on the basis of the above-described model, when an increased layer thickness at the center may be desired or a less pronounced compensation is desired, as previously discussed.

It should further be appreciated that the constants A, B may be readily determined by experiment, for instance, by depositing a specified material with a specified process recipe, however, at different temperatures and determining the layer thickness at different locations of the substrate, which may represent different precursor concentrations. From respective measurements, a deposition rate at the working point T₀,C₀ and the respective constants A, B may be determined. Thus, after determining a target temperature gradient, a respective temperature profile may be selected for obtaining the target temperature gradient. As previously discussed, the value determined by the above-specified model may represent an average temperature gradient so that an initial temperature gradient at the beginning of the actual deposition or treatment phase J3 may be selected on the basis of the average gradient and a respective temperature gradient at the end of this phase may be compared to the target temperature gradient. It should be appreciated that appropriate temperature profiles of the overheating phase for obtaining desired average or initial temperature gradients may be determined by experiment, for instance, by recording a temperature at the center 201C and at the edge 201E for a plurality of profiles and durations of the respective overheating phases J2 in order to obtain desired initial temperature gradients and, thus, an appropriate average temperature gradient.

The respective initial temperature gradient may also be selected with respect to the target layer thickness since a reduced layer thickness may, in general, be accomplished on the basis of shorter deposition or treatment times so that, in general, a moderately high value of the temperature gradient may be maintained over the entire deposition or treatment period, while, for longer deposition or treatment phases, a more pronounced stabilization of the temperatures between the edge 201E and the center 201C may be obtained. That is, the average temperature gradient may not be inverse proportional to the deposition time but may be over proportionally greater for shorter deposition times. Furthermore, in some illustrative embodiments, the respective overheating profile, as, for instance, described by curves B and C in FIG. 2a, may be adjusted individually for respective temperature zones of the reactor 150, for instance, the temperature zones 151A 151B, 151C (see FIG. 1b), so as to take into consideration zone specific characteristics. For example, respective measurements at the various temperature zones may be used for determining appropriate temperature profiles in order to obtain the desired target temperature gradient, as previously explained.

Consequently, a plurality of material layers may be formed on the basis of a thermally activated process using a process temperature profile, as described with reference to FIG. 2a, thereby providing the potential for enhancing overall process uniformity or potentially adjusting the thickness profile, for instance, by controllably creating laterally varying thickness profiles in order to compensate for non-uniformities of preceding or subsequent processes.

With reference to FIGS. 2c-2d, illustrative embodiments for forming a critical material layer on the basis of the above-described techniques may be described.

FIG. 2c schematically illustrates a cross-sectional view of a microstructure device 200, which, in the embodiment shown, may represent a semiconductor device receiving a plurality of transistor elements. The device 200 may comprise the substrate 201 which may represent any appropriate carrier material in combination with the respective material layers, such as, semiconductor layers, insulating materials, metals and the like as may be required for respective device features, such as transistors, capacitors, and the like. In the embodiment shown, the device features may comprise gate electrode structures 203 formed on the respective gate insulation layers 204. With respect to these components, the same criteria apply as previously explained with reference to the device 100. Furthermore, a material layer 205, such as a dielectric layer, a semiconductor layer and the like, may be formed above the substrate 201 and the device features. In one illustrative embodiment, the material layer 205 may be comprised of an appropriate material for forming sidewall spacer elements in a subsequent process step. In this case, the layer 205 may comprise two or more sub-layers, such as a silicon dioxide layer, a silicon nitride layer and the like, according to well-established spacer techniques. Consequently, the material layer 205 may be formed on the basis of process techniques, as previously described, wherein, in the embodiment shown, a substantially uniform layer thickness may be desired with respect to the center 201C and the edge 201E. For this purpose, the substrate 201 may be processed, for instance, in a respective reactor, such as the reactor 150 of FIG. 1b, while using a process temperature profile as explained with reference to FIG. 2a, wherein a temperature gradient ΔT may be used to substantially compensate for gas depletion at the center 201C, as previously discussed. As a consequence, during the process 206, which may be a deposition process on the basis of appropriate precursor materials in combination with an appropriate deposition pressure and deposition temperature, desired material(s) may be formed with enhanced thickness uniformity. In other cases, the process for forming the material layer 205 may comprise a surface treatment, such as an oxidation process, when the corresponding surface of the layer 205 comprises oxidizable portions or any other portions that undergo a chemical reaction, wherein the reaction rate may depend on the local concentration of a reactive component and the local temperature.

FIG. 2d schematically illustrates the device 200 in a further advanced manufacturing stage in which sidewall spacer elements 205A may be formed on the sidewalls of the gate electrode structures 203, wherein, due to the adjusted thickness profile of the layer 205, also a respective width of the spacer elements 205A may be adjusted on the basis of a desired profile. For instance, a uniform spacer width may be obtained in the regions 201C and 201E when forming the layer 205 with a substantially uniform thickness, while, in other cases, a varying spacer width may be created, if required. The spacers 205A may be formed on the basis of well-established etch techniques. Furthermore, an ion implantation process 207 may be performed, in which the gate electrode structures 203 and the spacers 205A may act as an implantation mask, thereby defining the lateral dopant profile of respective drain and source regions 208 or at least portions thereof. Hence, the characteristics of the drain and source regions 208 may be adjusted on the basis of the spacers 205A, wherein the width thereof may, in turn, be adjusted on the basis of the preceding deposition or treatment process 206.

As a result, the present disclosure provides techniques for forming material layers which, in some illustrative embodiments, may represent material layers of a thickness of approximately 50 nm and less, for instance, for forming layers in a range from approximately one to several tens of nanometers, wherein the across-substrate thickness profile may be adjusted during a thermally activated batch process by providing a temperature profile prior to actually forming the layer such that an increased temperature is obtained at the centers of the substrates during the process of actually forming the material layer. Consequently, a desired temperature gradient may be established prior to actively forming the material layer, for instance, by deposition, oxidation and the like in a low pressure ambient, wherein the global process temperature may be maintained at a desired temperature range, for instance, at a substantially constant process temperature to provide the desired overall deposition rate.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method for forming a material layer of a microstructure device, the method comprising:
generating a temperature profile in a process reactor comprising a plurality of substrates, said temperature profile including a temperature above a predetermined process temperature range;
establishing a process temperature within said predetermined process temperature range in said process reactor after generating said temperature profile; and
introducing a precursor gas component to initiate formation of said material layer above said plurality of substrates at said process temperature maintained within said predetermined process temperature range.

2. The method of claim 1, wherein said process temperature is maintained at a substantially constant value.

3. The method of claim 1, wherein said temperature profile comprises a maximum temperature that is approximately 100° C. above said predetermined process temperature range.

4. The method of claim 3, wherein said maximum temperature is approximately 10-60° C. above said predetermined temperature range.

5. The method of claim 1, wherein a thickness of said material layer is approximately 50 nm or less.

6. The method of claim 1, further comprising determining a target temperature gradient across each of said plurality of substrates and selecting said temperature profile on the basis of said target temperature gradient.

7. The method of claim 6, wherein determining said target temperature gradient comprises obtaining a relation between deposition rate, substrate temperature and precursor concentration and determining said target temperature gradient so as to obtain a substantially constant deposition rate.

8. The method of claim 1, wherein each of said plurality of substrates comprises circuit elements having at least one lateral dimension of approximately 50 nm or less.

9. The method of claim 8, wherein said circuit elements represent gate electrode structures of field effect transistors.

10. The method of claim 9, further comprising anisotropically etching said material layer to form sidewall spacers at sidewalls of said gate electrode structures.

11. The method of claim 1, wherein initiating formation of said material layer comprises initiating deposition of material of said material layer.

12. The method of claim 1, wherein initiating formation of said material layer comprises initiating oxidation of an exposed surface of said substrates.

13. A method, comprising:
determining a target temperature gradient across a specified type of surface for reducing a non-uniformity during a thermally activated process for forming a material layer above said specified type of surface;
generating a temperature profile in a reactor comprising one or more substrates on the basis of said target temperature gradient, each of said one or more substrates comprising a surface of said specified type; and
introducing a reactive gas component into said reactor at a substantially constant process temperature to initiate formation of said material layer.

14. The method of claim 13, wherein introducing said reactive component comprises introducing a precursor material for initiating a chemical vapor deposition process.

15. The method of claim 13, wherein introducing said reactive component comprises introducing an oxidizing component for initiating an oxidation process.

16. The method of claim 13, wherein said temperature profile comprises a temperature range that is above said substantially constant process temperature.

17. The method of claim 16, wherein a maximum temperature of said temperature range is approximately 100° C. or less above said substantially constant process temperature.

18. The method of claim 13, wherein a thickness of said material layer is approximately 50 nm or less.

19. The method of claim 13, wherein forming said material layer comprises forming at least one of a silicon nitride layer, a silicon dioxide layer and a polysilicon layer.

20. The method of claim 13, wherein determining said target temperature gradient comprises establishing a relation between rate of material generation, a temperature of said specified type of surface and a concentration of said reactive component and determining said target temperature gradient by using said relation to obtain a substantially constant rate of material generation.

21. A method comprising:
creating a temperature gradient across a surface of each of a plurality of substrates, said temperature gradient including at least one surface temperature that is above a predefined process temperature, said surface comprising a device feature;
forming a material layer above said surface and said device feature substantially at said process temperature; and
removing a portion of said material layer to form a sidewall spacer at sidewalls of said device feature.

22. The method of claim 21, wherein a thickness of said material layer is approximately 50 nm or less.
